(19) United States
(12) Patent Application Publication
(10) Pub. No.: US 2022/0122838 A1
(43) Pub. Date: Apr. 21, 2022

(54) Approaches for Fabricating N-Polar AlxGa1-xN Templates for Electronic and Optoelectronic Devices

(71) Applicant: University of South Carolina, Columbia, SC (US)

(72) Inventor: Asif Khan, Irmo, SC (US)

(73) Assignee: University of South Carolina, Columbia, SC (US)

(21) Appl. No.: 17/504,700

(22) Filed: Oct. 19, 2021

Related U.S. Application Data
(60) Provisional application No. 63/094,413, filed on Oct. 21, 2020.

(51) Int. Cl. H01L 21/02; H01L 29/66; H01L 21/48

(52) U.S. Cl. CPC H01L 21/0254; H01L 21/0242; H01L 21/4871; H01L 21/02502; H01L 29/66462; H01L 21/02458

(57) ABSTRACT

AlN templates, with excellent thermal conductivity formed via Air-pocket assisted Pulsed Lateral Epitaxy that possess reverse grading (from AlGaN to GaN) in the contacts region, which for the N-polar epilayers should lead to electron accumulation.

### TECHNICAL FIELD

The subject matter disclosed herein is generally directed to AlN templates, with excellent thermal conductivity formed via Air-pocket assisted Pulsed Lateral Epitaxy that possess reverse grading (from AlGaN to GaN) in the contacts region, which for the N-polar epilayers should lead to electron accumulation.

### BACKGROUND

Ga-polar III-N devices have undergone significant performance improvement. They are now being commercialized by several large US based power electronics companies such as Transphorm, EPC and Texas Instruments. To-date there has been very little research aimed at growing N-polar ultra-wide bandgap AlₓGa₁₋ₓN layers and heterojunctions. N-polar high electron mobility transistors (HEMTs), specifically those with AlₓGa₁₋ₓN channels, have not been reported. The majority of the reported III-Nitride N-polar research has focused on the development of GaN channel devices with thin AlN/AlₓGa₁₋ₓN buffer layers on sapphire or SiC substrates. SiC substrates especially those with the correct orientation for N-polar growths are expensive and difficult to obtain as they are not the same as used for SiC power electronics. As expected, growth on low cost sapphire or silicon leads to severe thermal management issues for power electronic devices. Note, thermal management is a critical issue for both the Ga- and N-polar AlₓGa₁₋ₓN high electron mobility transistors. For an effective cooling of the active channel, the device epilayer structure needs to be grown on a high thermal conductivity thick layer/substrate for an efficient heat spreading. FIG. 1 lists the thermal conductivity of commonly available/used substrates for III-N electronic and optoelectronic devices.

Accordingly, it is an object of the present disclosure to provide AlN templates with excellent thermal conductivity.

Citation or identification of any document in this application is not an admission that such a document is available as prior art to the present disclosure.

### SUMMARY

The above objectives are accomplished according to the present disclosure by providing in one embodiment, a method for growing low-defect, crack free AlN layers. He method may include providing a substrate, forming at least one AlN layer upon the substrate via pulsed epitaxy such that the AlN layers has a random-microgrooved template, modifying growth conditions to form lateral epitaxy from at least one sidewall of the at least one AlN layer. Further, the substrate may comprise sapphire. Still yet, air pockets may be formed in the at least one AlN layer. Further again, the at least one AlN layer may have a defect density value of substantially 1-3×108 cm-2. Moreover, an ultrawide band gap AlxGa1-xN template may be formed over the substrate. Still again, the at least one AlN layer random-microgrooved template may be 16-25 μm thick. Furthermore, laser lift-off may be performed on the at least one AlN layer. Still yet further, the method may include fabricating at least one vertically conducting UWBG AlxGa1-xN device by growing at least one epilayer over an ultrawide band gap AlxGa1-xN substrate to form at least one wafer, bonding the at least one wafer to a temporary carrier, performing laser liftoff of the at least one wafer, forming at least one backside n-contact on a N-polar face of the at least one wafer, bonding the at least one backside n-contact to at least one metallic preform; removing the temporary carrier; and fabricating at least one vertical conduction device on a side of the at least one wafer opposite the n-contact. Yet further, the method may include reverse grading, from AlGaN to GaN, in an area containing the at least one n-contact. Further yet, the method may include wafer bonding and excimer laser liftoff to form an N-polar AlN substrate for growth of a high-electron-mobility transistor. Still again, the method may include removing the substrate and replacing the substrate with a high-thermal conductivity metal preform. Yet again, the method may include forming a heat sink by introducing at least one submount plate to the at least one AlN layer, depositing a Ti/N/Ti/Ni/Ti/Ni buffer layer, deposting a Ti/Au wetting layer, depositing AuSn solder followed by soldering; and performing substrate liftoff. Further, the submount plate may be Cu or CuW. Still further, the method may include introducing at least one AlN spacer, at least one GaN layer and at least one low temperature AlN layer between the AlxGa1-xN template and the substrate.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows thermal conductivity and cost of substrate materials for III-N devices.

FIG. 2 shows Source-Drain Characteristic curves for identical geometry Al_{0.25}Ga_{0.75}N—GaN HEMTs over sapphire and SiC substrates.

FIG. 3 shows 12 μm thick AlN layers over sapphire substrates fabricated using air-pocket assisted lateral epitaxy.

FIG. 4 shows an X-section TEM image of the AlN/sapphire interfacial region showing the presence of air-pockets for strain relaxation.

FIG. 5 shows surface morphology of a 16 μm thick AlN layer over sapphire that was deposited using air-pocket assisted lateral epitaxy.

FIG. 6 shows bulk thermal conductivity of thick AlN/sapphire templates and that of bulk AlN substrates from Nagoya University and Hexatech Inc.

FIG. 7 shows GaN-channel and UWBG AlGaN channel HEMTs over quasi-bulk AlN templates over sapphire substrates.

FIG. 8 high-temperature AlN wafer bonding using Face-to-face anneal under flowing nitrogen.

FIG. 9 shows a new approach to fabricating vertically conducting UWBG AlₓGa₁₋ₓN devices (x>0.4).

FIG. 10 shows a new approach to fabricating N-polar UWBG AlₓGa₁₋ₓN devices (x>0.4).

FIG. 11 shows at (A) N-polar AlGaN channel lateral conduction HFET structure and at (B) N-Polar AlGaN channel vertical conduction HEMT.

FIG. 12 shows at: (a) The device structure of the AlGaN/GaN HEMT, Optical images of the HEMT (b) before and, (c) after laser lift-off.

FIG. 13 shows frequency dependent C-V characteristics of the AlGaN/GaN HEMT: (a) before and, (b) after laser lift-off. Inset figures show the gate leakage characteristics.

FIG. 14 shows at: (a) Raman spectra E2 (high) and A1 (LO) peaks of the GaN/AlGaN HEMT before and after the laser lift-off process showing redshift of 2.42 cm-1, Raman strain mapping of E2 phonon frequency for the access region of (b) as-fabricated, and (c) laser lifted-off HEMT

FIG. 15 shows LLO transfer of an AlN heat spreader onto commercial submount packaging.

FIG. 16 shows an example of 1 mm blocks that have been transferred from the sapphire, and the characterization of their optoelectronic integrity using cathodoluminescence.

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the singular forms “a”, “an”, and “the” include both singular and plural referents unless the context clearly dictates otherwise.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g. given data set, art accepted standard, and/or with e.g. a given confidence interval (e.g. 90%, 95%, or more confidence interval from the mean), such as variations of +/−10% or less, +/−5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

The term “optional” or “optionally” means that the subsequent described event, circumstance or substituent may or may not occur, and that the description includes instances where the event or circumstance occurs and instances where it does not.

As used interchangeably herein, the terms “sufficient” and “effective,” can refer to an amount (e.g. mass, volume, dosage, concentration, and/or time period) needed to achieve one or more desired and/or stated result(s). For example, a therapeutically effective amount refers to an amount needed to achieve one or more therapeutic effects.

As used herein, “tangible medium of expression” refers to a medium that is physically tangible or accessible and is not a mere abstract thought or an unrecorded spoken word. “Tangible medium of expression” includes, but is not limited to, words on a cellulosic or plastic material, or data stored in a suitable computer readable memory form. The data can be stored on a unit device, such as a flash memory or CD-ROM or on a server that can be accessed by a user via, e.g. a web interface.

As used herein, the terms “weight percent,” “wt %,” and “wt. %,” which can be used interchangeably, indicate the percent by weight of a given component based on the total weight of a composition of which it is a component, unless otherwise specified. That is, unless otherwise specified, all wt % values are based on the total weight of the composition. It should be understood that the sum of wt % values for all components in a disclosed composition or formulation are equal to 100. Alternatively, if the wt % value is based on the total weight of a subset of components in a composition, it should be understood that the sum of wt % values the specified components in the disclosed composition or formulation are equal to 100.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present disclosure. Thus, appearances of the phrases “in one embodiment,” “in an embodiment,” or “an example embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the disclosure. For example, in the appended claims, any of the claimed embodiments can be used in any combination.

All patents, patent applications, published applications, and publications, databases, websites and other published materials cited herein are hereby incorporated by reference to the same extent as though each individual publication, published patent document, or patent application was specifically and individually indicated as being incorporated by reference.

This disclosure hereby incorporates U.S. Provisional Patent Application 63/094,419 in its entirety.

The current disclosure has explored AlxGa1-xN channel Ga-polar High Electron Mobility Transistors (“HEMTs”). This work has uncovered a major technical challenge, which is the difficulty in the formation of low-resistivity ohmic contacts to ultra-wide bandgap (“UWBG”) AlxGa1-xN layers and heterojunctions. It arises from the high Schottky barrier height and the low-doping efficiency in UWBG AlxGa1-xN layers with alloy compositions in excess of 60%. Strategies such as using reverse composition grading in the contact region (high Al-composition to GaN) do not work very well because the reverse grading leads to a depleted region due to the polarization doping. A high n-type doping of this reverse graded composition region only partially mitigates the problem. To date the lowest contact resistivity that we reported was 1-2 Ω-mm which is still too high and limit the device high frequency and high-power performance. The depletion issue in the contact region can be completely avoided if the material is N-polar. In that case there will be electron accumulation favoring the ohmic-contact formation.

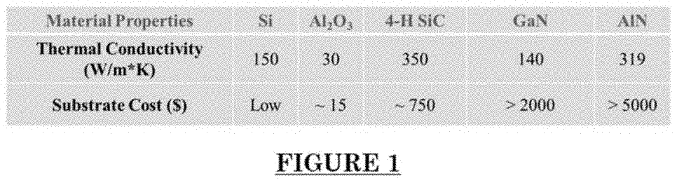

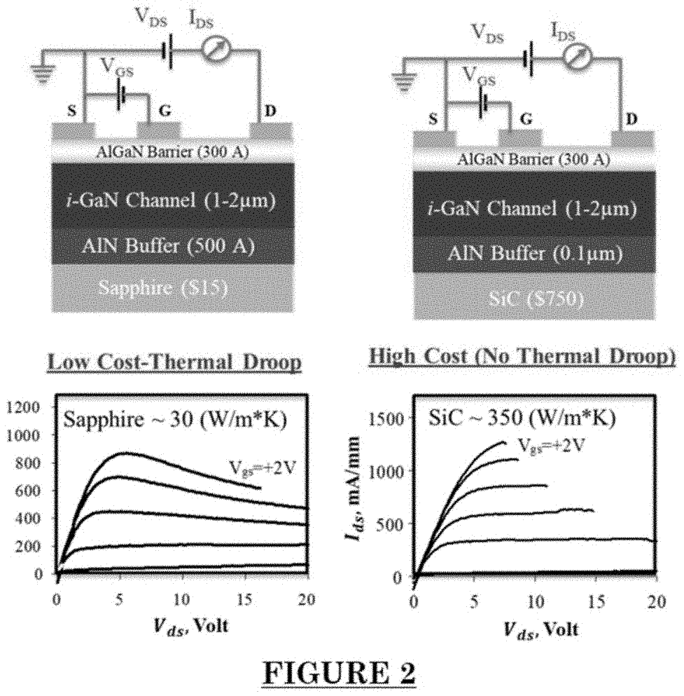

As FIG. 1 shows, bulk SiC, and bulk AlN have thermal conductivities approximately 2-3 times higher than Si or bulk GaN and a factor of 10 higher than sapphire. However, the cost of bulk substrates (SiC, GaN or AlN) is substantially higher than sapphire or Si. HEMT devices on sapphire substrates show a clear thermal droop and cannot be used at full bias. This droop is absent in bulk SiC or bulk AlN based devices (see FIG. 2).

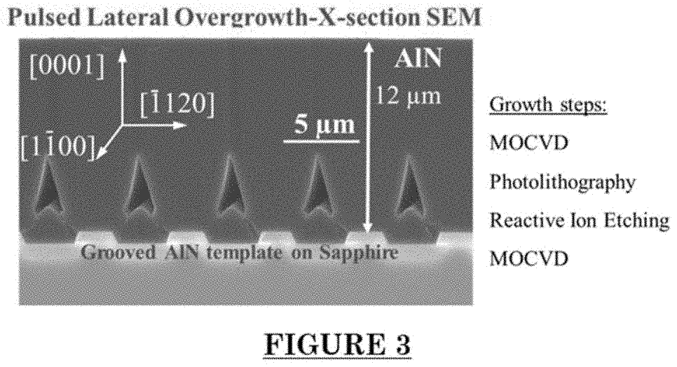

In the past, other work developed and reported on Air-pocket assisted pulsed epitaxy (PLE) to grow high quality AlN layers with thicknesses well over 10 μm. Results from this report are shown in FIG. 3. The strain related cracking of very thick AlN layers is avoided by first fabricating a grooved AlN template structure on sapphire (by photolithography and reactive ion etching) and then using pulsed lateral epitaxy from the slanted facets to coalesce the layers. The air-pockets formed in the process relieve stress and the lateral epitaxy leads to an overall reduction of defects from 3-5×10⁹ cm⁻² in conventional AlN epi-layers to about 1-3×10⁸ cm⁻² in the thick PLE AlN layers. However, the required ex-situ processing makes the approach high-cost and time consuming.

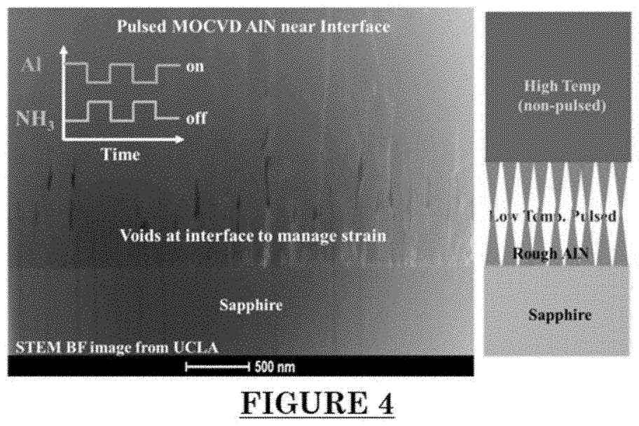

Recently, using a modified version of the inventors' past approach under a MURI program, we have succeeded in growing low-defect crack-free AlN layers as thick as 25 μm, over sapphire substrates. The technical strategy we used was a variation of the technique for the layers of FIG. 3. We first created a rough AlN layer by pulsed epitaxy which acts as a random micro-grooved template. This is followed by modifying the growth conditions to lead to lateral epitaxy from the sidewalls of the rough layer facets. This, like before, yielded material with air-pockets thereby relieving the strain and enabling growth of crack free 16-25 μm thick layers. (see FIG. 4). The lateral epitaxy procedure, as before, leads to defect reduction to a value around 1-3×10⁸ cm⁻².

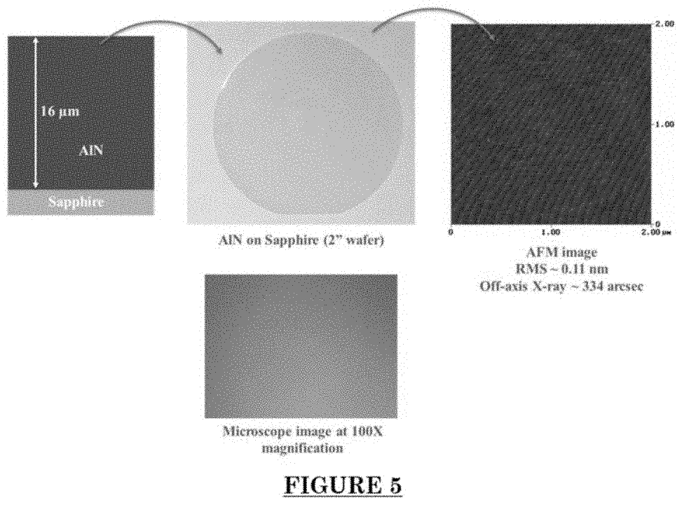

In FIG. 5 we have included a microscope, AFM and an SEM image of a 16 μm thick high-quality low defect crack free AlN layer on sapphire. The RMS surface roughness was measured to be 0.11 nm and the off-axis X-ray linewidth was 340 arc-sec which translates to a defect density of around (1-3)×10⁸ cm⁻² which was also confirmed by etch-pit density (EPD) measurements.

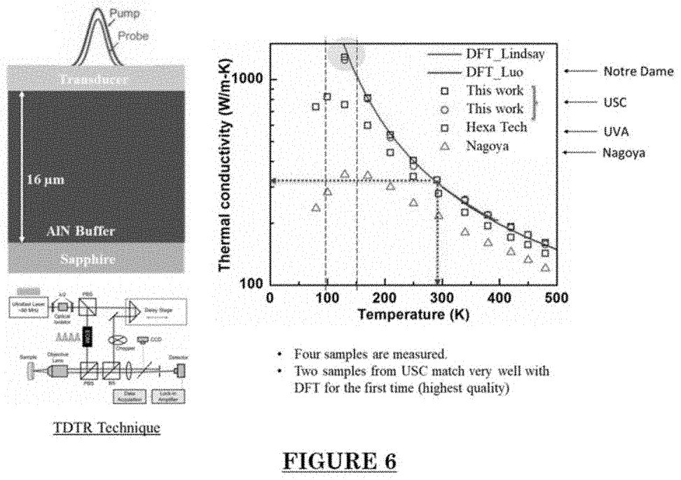

The thermal conductivity of our high-quality 16 μm thick AlN layers was measured using a TDTR technique at University of Virginia (UVa). It was found to be equal to or better than bulk AlN samples at room-temperatures. Even at low temperatures it exceeded that of bulk AlN substrates from Hexatech Inc. Moreover, the measured values perfectly matched the DFT calculations performed by our collaborators at Georgia Tech and UVa. Noting that our extended defects are approximately 10⁴ higher than those in bulk AlN substrates, we can conclude that, contrary to past beliefs, the thermal conductivity is not controlled by extended defects. The measured thermal conductivity data for our AlN/sapphire templates are included in FIG. 6.

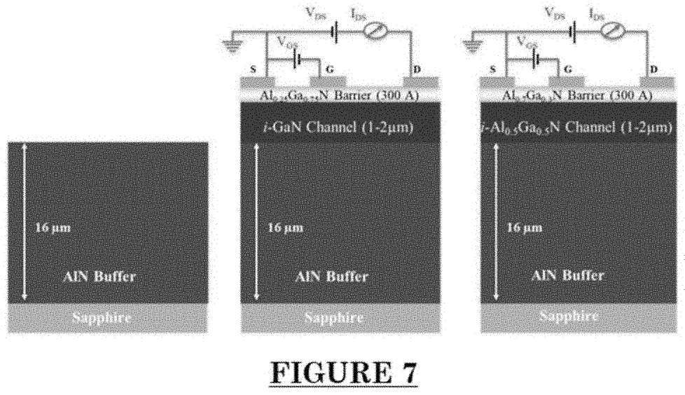

We believe our 16-25 μm thick quasi-bulk AlN templates, with their excellent thermal conductivity, can be a potential low-cost replacement for SiC substrates for Ga-polar HEMT devices. See FIG. 7.

Also, like AlN, our Air-pocket assisted Pulsed Lateral Epitaxy approach can be tailored to produce thick UWBG AlₓGa₁₋ₓN templates over sapphire to serve as quasi-bulk AlₓGa₁₋ₓN substrates. To the best of our knowledge, to date, there are no reports of such UWBG AlₓGa₁₋ₓN (x>0.4) substrates or thick templates over sapphire.

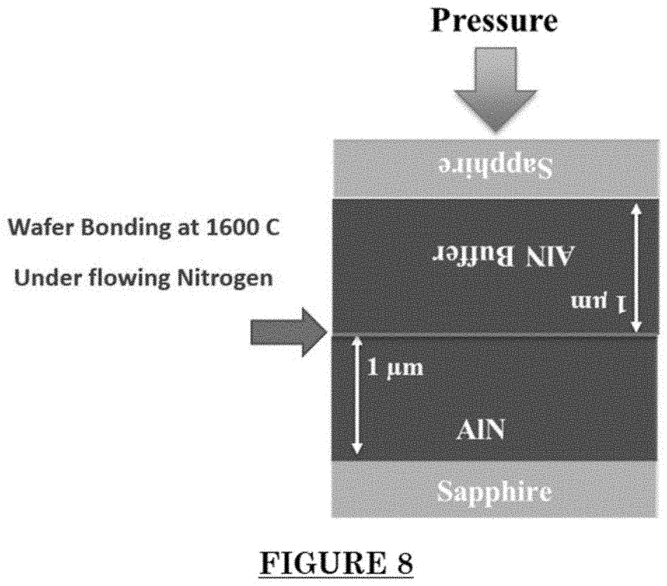

Note, in the past our group demonstrated deep ultraviolet UVC LEDs (λₑₘᵢₛₛᵢₒₙ˜280 nm) where the sapphire substrate was lifted off using an excimer laser. Recently, the inventors have succeeded in wafer bonding AlN/sapphire templates with a high temperature face-to-face anneal. This procedure is schematically shown in FIG. 8 below.

Combining the laser lift-off (LLO) with either thick AlN or UWBG AlₓGa₁₋ₓN/sapphire templates provides us a unique platform to conduct fundamental materials research in Ga-polar and N-polar UWBG materials. New unique device configurations can then be developed that will eliminate issues, such as high contact resistivity that plague the current Ga-polar UWBG AlGaN devices.

Further embodiments are illustrated in the following Examples which are given for illustrative purposes only and are not intended to limit the scope of the disclosure.

### Examples

Now having described the embodiments of the present disclosure, in general, the following Examples describe some additional embodiments of the present disclosure. While embodiments of the present disclosure are described in connection with the following examples and the corresponding text and figures, there is no intent to limit embodiments of the present disclosure to this description. On the contrary, the intent is to cover all alternatives, modifications, and equivalents included within the spirit and scope of embodiments of the present disclosure. The following examples are put forth so as to provide those of ordinary skill in the art with a complete disclosure and description of how to perform the methods and use the probes disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is at or near atmospheric. Standard temperature and pressure are defined as 20° C. and 1 atmosphere.

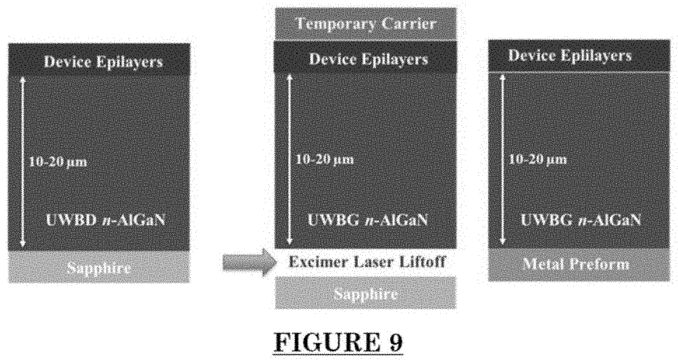

As a first example, we can fabricate vertically conducting UWBG AlₓGa₁₋ₓN devices. For this the device epilayers can be grown over the thick UWBG AlₓGa₁₋ₓN/sapphire templates. Then the wafer can be bonded to a temporary carrier wafer for laser liftoff. Post liftoff, we can form the backside n-contact on the N-polar face and this metal contact can be bonded to a metallic preform using a process that we have routinely used in the past for flip-chip bonding of UVC LEDs. Finally, the vertical conduction devices can be fabricated on the top side after the removal of the temporary carrier wafer. This process sequence is schematically shown in FIG. 9 below.

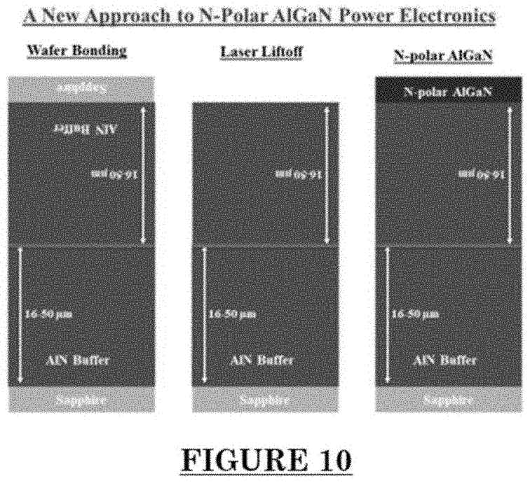

As a second example, our thick AlN/sapphire templates in conjunction with high-temperature wafer bonding and excimer laser liftoff can be used to produce high quality N-polar AlN substrates (over sapphire) for subsequent growth of HEMTs or other device types. In FIG. 10, we include a schematic of the fabrication approach that can lead to very thick N-polar AlN templates over sapphire. These in essence will serve as low-cost quasi-bulk AlN substrates.

Note, as described earlier in FIG. 9, the sapphire substrate can also be removed from the devices of FIG. 10 and replaced with a high-thermal conductivity metal preform.

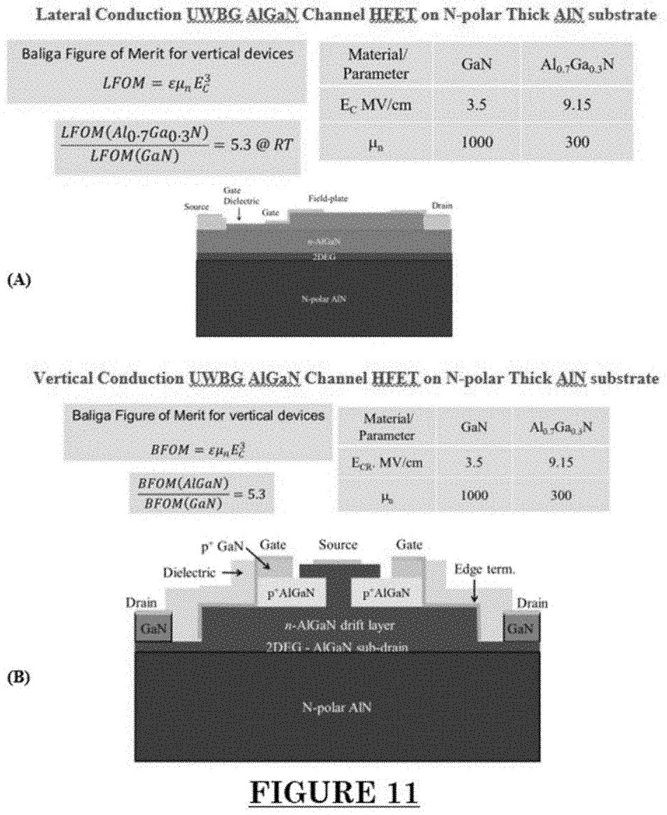

In the FIG. 11, we include examples of lateral and vertical conduction N-polar UWBG HEMTs that can be combined with the thick N-polar AlN template structure of FIG. 10. It should be noted that the higher breakdown field should lead to the Baliga Figure of Merit of these devices to be a factor of 1.8 and 3.5 higher than those with GaN channel layers.

The key feature of these two devices is the reverse grading (from AlGaN to GaN) in the contacts region, which for the N-polar epilayers should lead to electron accumulation.

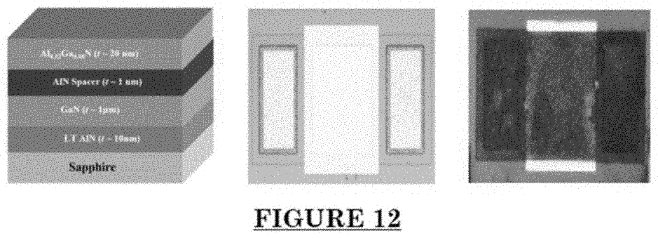

FIG. 12 shows at (a) The device structure of the AlGaN/GaN HEMT, Optical images of the HEMT (b) before and, (c) after laser lift-off. Demonstrated laser lift-off (LLO) of AlGaN/GaN HEMT's transistors onto another substrate, enabling an alternative pathway for the integration of DUV LED's with GaN electronics for photonic integrated circuits (PIC's). In one embodiment, at least one AlN spacer, at least one GaN layer and at least one low temperature AlN layer may be introduced between the AlxGa1-xN template and the substrate.

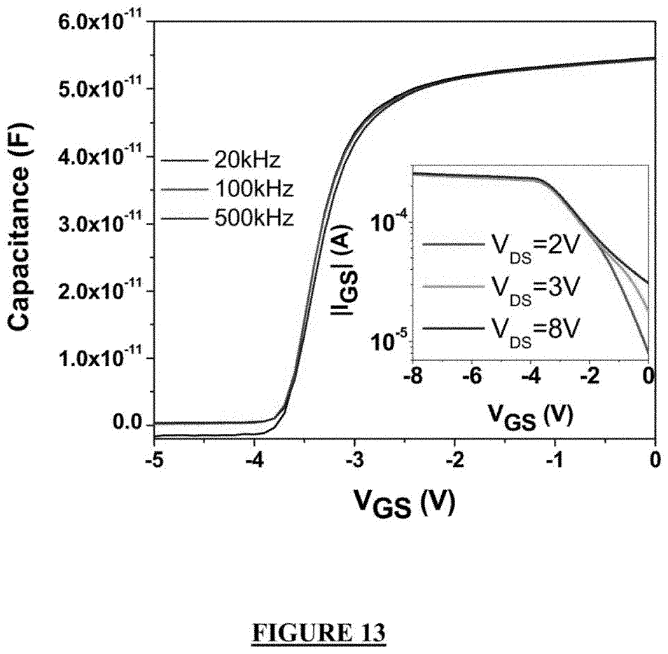

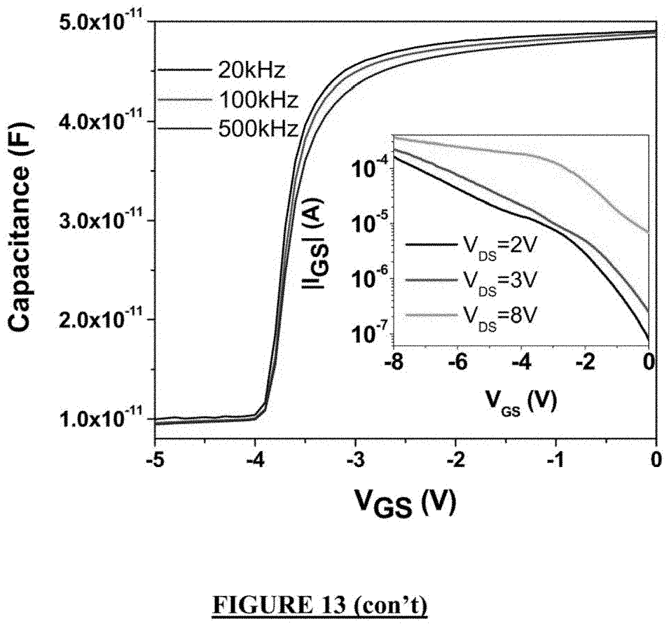

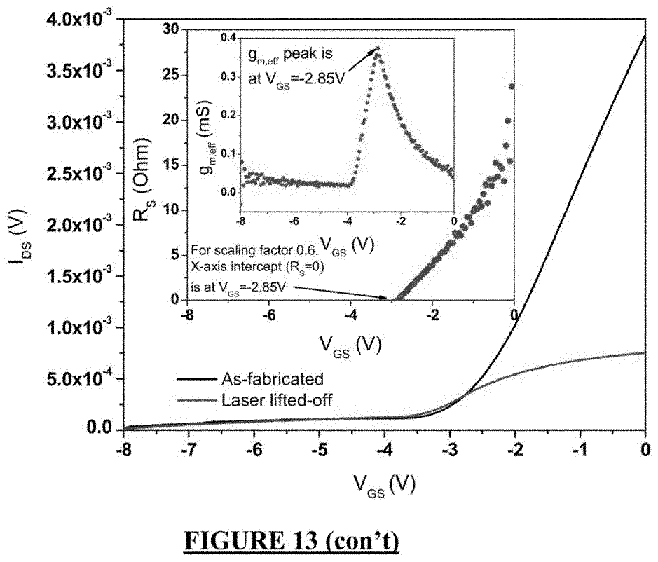

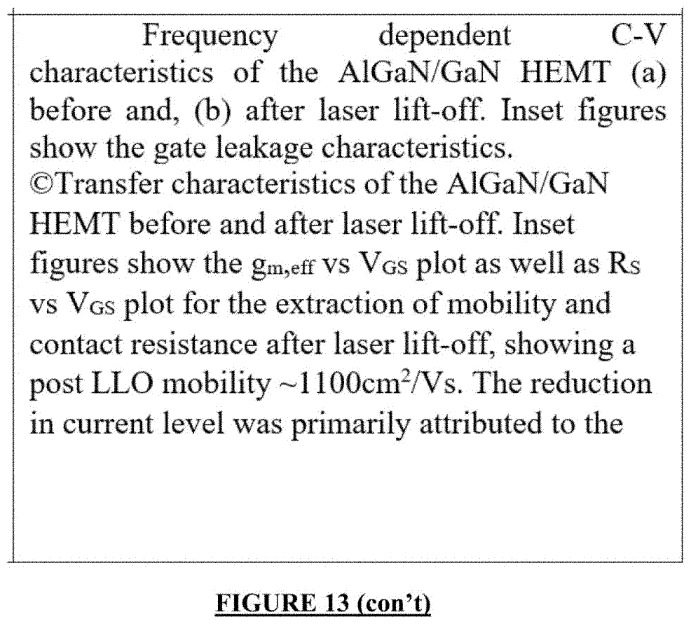

FIG. 13 shows frequency dependent C-V characteristics of the AlGaN/GaN HEMT at: (a) before and, (b) after laser lift-off. Inset figures show the gate leakage characteristics.

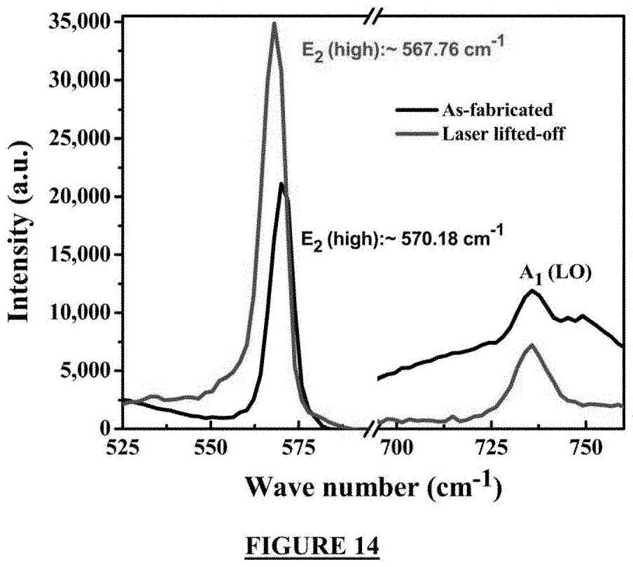

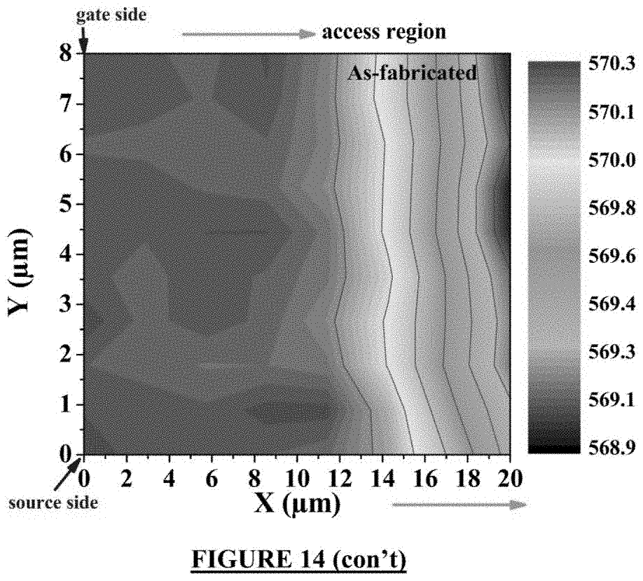

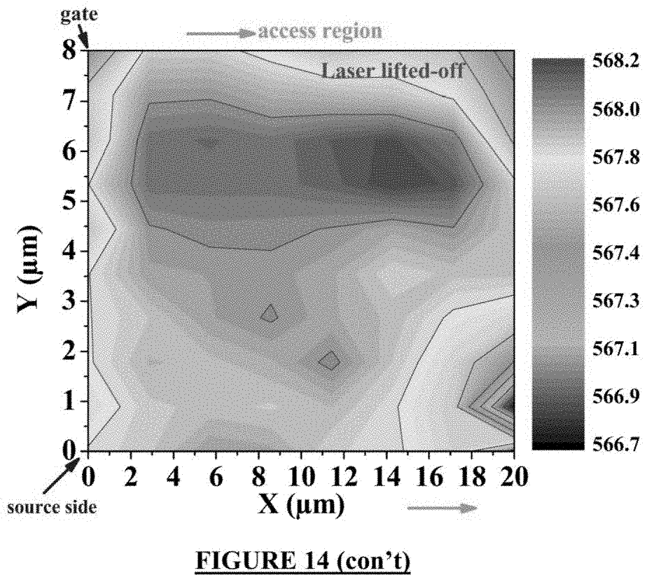

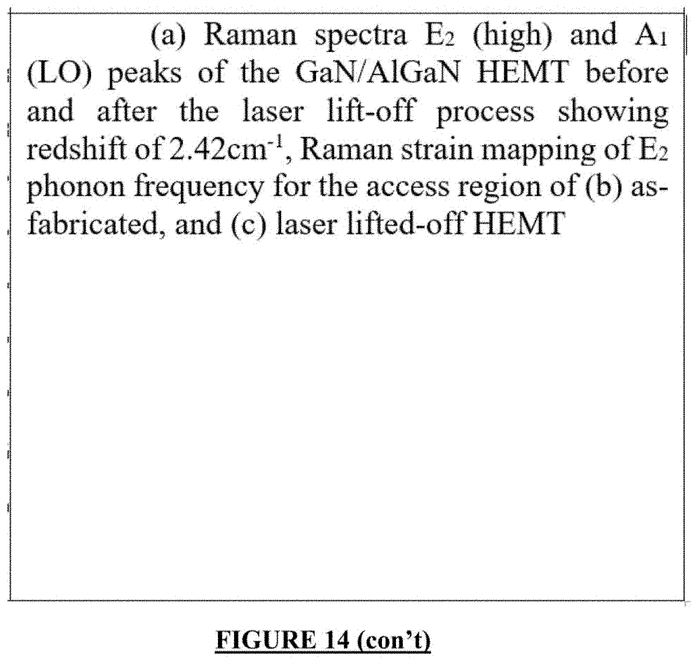

FIG. 14 shows at: (a) Raman spectra E2 (high) and A1 (LO) peaks of the GaN/AlGaN HEMT before and after the laser lift-off process showing redshift of 2.42 cm-1, Raman strain mapping of E2 phonon frequency for the access region of (b) as-fabricated, and (c) laser lifted-off HEMT

The goal here was to develop the ability to transfer a fabricated AlGaN/GaN high electron mobility transistor (HEMT) onto an arbitrary substrate using an excimer laser lift-off (LLO) process. This will enable the integration of the Ga-rich side of the AlGaN alloy system with the Al-rich side of the system (which the DUV LED's are a part of), by circumventing the challenges with in-situ crystal growth incompatibilities between GaN (˜900 C) and AlGaN (>1000 C). By transferring the device to a host substrate, after which the sapphire is removed, the N-polar side of the GaN HEMT is revealed, enabling ease of contact formation for subsequent integration with DUV LED's. FIG. 12 shows the transferred device, while FIG. 13 shows the electrical characteristics before and after LLO transfer. The threshold voltage was unchanged, whereas the current level decreased by 4×. Careful analysis of the transfer characteristics revealed this decrease to be due to a ˜30% reduction in carrier mobility, while the rest of the decrease is due to degradation of the ohmic contacts during transfer. We are currently developing a technique to form ohmic contacts after LLO transfer. Raman measurements in FIG. 14 show that a small amount of stress ˜1 GPa is relieved due to the transfer, although not enough to cause a significant change in the carrier concentrations measured in FIG. 13 at b by capacitance-voltage.

Thick AlN Template LLO as Heat Sinks for High Power Electronics.

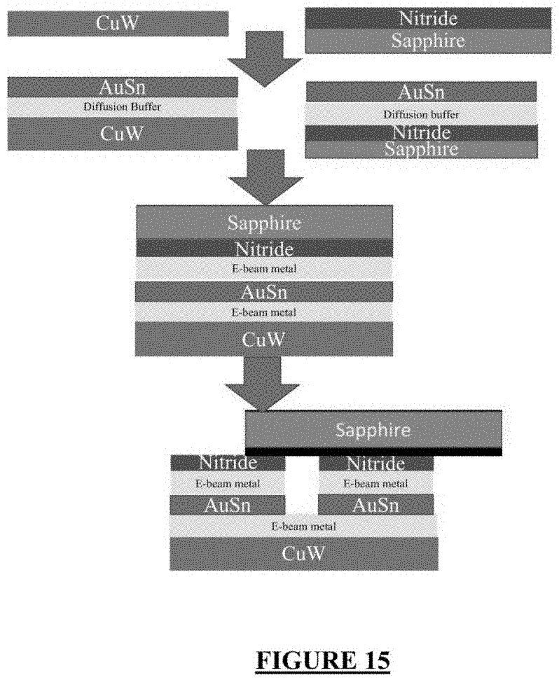

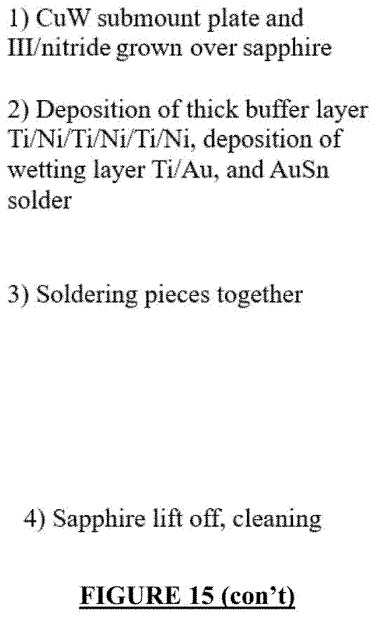

The first step involved development of thick ˜16 um thick AlN templates grown on sapphire using a novel growth technique enabling strain management for thick layers in a single growth process. We showed that these layers could be scaled to as thick as needed. If they are too thick, however, they are unsuitable as heat spreaders, as there will be too much series thermal resistance. Here, we demonstrate LLO transfer of this AlN heat spreader onto commercial submount packaging used in semiconductor packaging. The key steps are listed in FIG. 15, after which the LLO is performed through the back of the double side polished sapphire in step 4, see FIG. 15. This standalone AlN on metal packaging in now an ideal heat spreader in semiconductor power electronics for thermal management. The submount may be Cu or CuW.

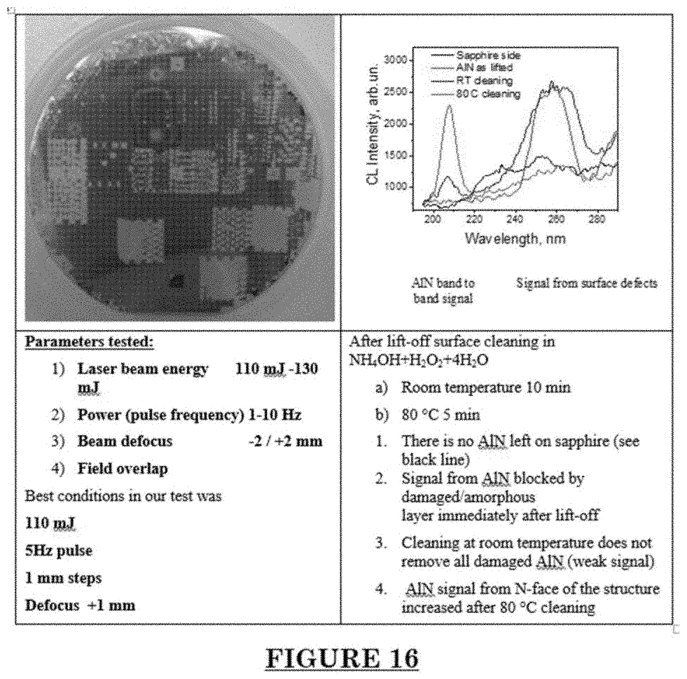

FIG. 16 shows an example of 1 mm blocks that have been transferred from the sapphire, and the characterization of their optoelectronic integrity using cathodoluminescence. Immediately after LLO transfer, the surface contains metallic and amorphous contamination that prevents the underlying bulk signal to be seen. After cleaning with ammonium hydroxide, this damage layer is removed, allowing the transferred layer to be clearly observed. Further optimization of the cleaning is likely needed, including acid cleans for metal removal, although this must be done in a manner not damaging to the metallic solders and submounts.

Various modifications and variations of the described methods, pharmaceutical compositions, and kits of the disclosure will be apparent to those skilled in the art without departing from the scope and spirit of the disclosure. Although the disclosure has been described in connection with specific embodiments, it will be understood that it is capable of further modifications and that the disclosure as claimed should not be unduly limited to such specific embodiments. Indeed, various modifications of the described modes for carrying out the disclosure that are obvious to those skilled in the art are intended to be within the scope of the disclosure. This application is intended to cover any variations, uses, or adaptations of the disclosure following, in general, the principles of the disclosure and including such departures from the present disclosure come within known customary practice within the art to which the disclosure pertains and may be applied to the essential features herein before set forth.

What is claimed is:

1. A method for growing low-defect, crack free AlN layers comprising:
providing a substrate;
forming at least one AlN layer upon the substrate via pulsed epitaxy such that the AlN layers is configured as a random-microgrooved template; and
modifying growth conditions to form lateral epitaxy from at least one sidewall of the at least one AlN layer.

2. The method of claim 1, wherein the substrate comprises sapphire.

3. The method of claim 1, wherein air pockets are formed in the at least one AlN layer.

4. The method of claim 1, wherein the at least one AlN layer has a defect density value of substantially 1-3×108 cm-2.

5. The method of claim 1 further comprising, forming an ultrawide band gap AlxGa1-xN template over the substrate.

6. The method of claim 1, wherein the at least one AlN layer random-microgrooved template is 16-25 μm thick.

7. The method of claim 1 further comprising, conducting laser lift-off of the at least one AlN layer.

8. The method of claim 1 further comprising, fabricating at least one vertically conducting UWBG AlxGa1-xN device via:
growing at least one epilayer over an ultrawide band gap AlxGa1-xN substrate to form at least one wafer;
bonding the at least one wafer to a temporary carrier;
performing laser liftoff of the at least one wafer;
forming at least one backside n-contact on a N-polar face of the at least one wafer;
bonding the at least one backside n-contact to at least one metallic preform;
removing the temporary carrier; and
fabricating at least one vertical conduction device on a side of the at least one wafer opposite the n-contact.

9. The method of claim 8 further comprising reverse grading, from AlGaN to GaN, in an area containing the at least one n-contact.

10. The method of claim 1 further comprising, wafer bonding and excimer laser liftoff to form an N-polar AlN substrate for growth of a high-electron-mobility transistor.

11. The method of claim 1 further comprising, removing the substrate and replacing the substrate with a high-thermal conductivity metal preform.

12. The method of claim 1 further comprising, forming a heat sink via:
introducing at least one submount plate to the at least one AlN layer;
depositing a Ti/N/Ti/Ni/Ti/Ni buffer layer;
deposting a Ti/Au wetting layer;
depositing AuSn solder followed by soldering; and
performing substrate liftoff.

13. The method of claim 12, wherein the submount plate is Cu or CuW.

14. The method of claim 5 further comprising, introducing at least one AlN spacer, at least one GaN layer and at least one low temperature AlN layer between the AlxGa1-xN template and the substrate.
